(19) United States
(12) Patent Application Publication
(10) Pub. No.: US 2014/0358470 A1
(43) Pub. Date: Dec. 4, 2014

(54) EVALUATING DEVICE, AND ELECTRIC POWER CONSERVATION PLANNING DEVICE AND METHOD

(71) Applicant: Azbil Corporation, Tokyo (JP)

(72) Inventors: Mayumi MIURA, Tokyo (JP); Masato TANAKA, Tokyo (JP)

(73) Assignee: AZBIL CORPORATION, Tokyo (JP)

(21) Appl. No.: 14/289,135

(22) Filed: May 28, 2014

(30) Foreign Application Priority Data
May 28, 2013 (JP) 2013-111577

(51) Int. Cl. G01K 1/02; G01R 21/133

(52) U.S. Cl. CPC G01K 1/022; G01R 21/133
USPC 702/130

(57) ABSTRACT

An evaluating device includes an environment information controlling portion that obtains, for each individual customer, environment information during an electric power conservation period for customers who have performed electric power conservation measures, an environment information storing portion that stores environment information obtained from the environment information controlling portion, and an environment evaluating portion that calculates, for each individual customer, an environmental degradation level indicating the level of degradation experienced by the customer during previous electric power conservation periods, based on environment information stored in the environment information storing portion.

### CROSS REFERENCE TO RELATED APPLICATION

This application claims priority under 35 U.S.C. §119 to Japanese Patent Application No. 2013-111577, filed on May 28, 2013, the entire content of which being hereby incorporated herein by reference.

### FIELD OF TECHNOLOGY

The present invention relates to an evaluating device for evaluating the degree of degradation experienced by a customer during previous power conservation periods, and a power conservation planning device for selecting a customer to be subject to power conservation using the evaluating device.

### BACKGROUND

A demand controlling device for performing reliable demand control while ascertaining the effect on occupants and tenants through controlling facilities and equipment after performing highly accurate and rapid demand (electric power consumption) forecasting, evaluation of facilities and equipment to be subject to demand control based on the demand forecasting, and notification of the occupants or tenants of regarding the detail of the control of the facilities and equipment has been proposed. See, for example, Japanese Unexamined Patent Application Publication 2011-193639 (“the JP '639”).

Moreover, there has been a proposal for an electric power demand controlling device for storing, for each customer, a sensitivity that indicates the probability that the customer will agree to a request for electric power conservation, wherein, if the forecasted electric power demand exceeds a target value that is set in advance, a customer for performing demand regulation is selected based on the sensitivities. See, for example, Japanese Unexamined Patent Application Publication 2011-254582 (“the JP '582”).

In order for an aggregator company that handles a plurality of customer to secure power for handling tight electric power supply (demand regulation reserve power), it is necessary to make it easy to obtain the cooperation of the customers in cutting back electric energy use. However, with the technologies disclosed in the JP '639 and the JP '532, the notification of the customer regarding the detail of demand control for facilities and equipment (cessation or modification of operation), and the selection of customers for performing regulation of demand were achieved, but no means for making it easier to obtain cooperation from the customer in energy conservation were produced.

The present invention was created in order to solve the problem set forth above, and an aspect thereof is to achieve means for facilitating garnering cooperation of customers through evaluating the degree of degradation experienced by the customers in electric power conservation periods in the past.

### SUMMARY

An evaluating device according to the present disclosure includes: an environment information controlling portion that obtains, for each individual customer, environment information during an electric power conservation period for customers who have performed electric power conservation measures; an environment information storing portion that stores environment information obtained from the environment information controlling portion; and an environment evaluating portion that calculates, for each individual customer, an environmental degradation level indicating the level of degradation experienced by the customer during previous electric power conservation periods, based on environment information stored in the environment information storing portion.

The evaluating device according to the present disclosure is the first structural example, wherein: the environment evaluating portion includes: an environment evaluation index value deriving portion that calculates an environment evaluation index value for evaluating the environment of the customer from the environment information; and environmental degradation level calculating portion that evaluates whether or not the environment evaluation index value is outside of an acceptable range, and that calculates an environmental degradation level based on the evaluation result.

Moreover, the evaluating device according to the present disclosure is the first structural example, wherein: the environmental degradation level calculating portion calculates, as the environmental degradation level, the time over which the environment evaluation index value is outside of the acceptable range extends, within the electric power conservation period, or calculate, as the environmental degradation level, an integral value of the environment evaluation index value that is outside of the acceptable range during the electric power conservation period.

Moreover, the electric power conservation planning device according to the present disclosure includes: an evaluating device as set forth in any one of the above structural examples; and a customer selecting portion that selects candidate customers, to be subject to electric power conservation, in ascending order starting with the customer for which the environmental degradation level calculated by the evaluating device is smallest.

Moreover, the electric power conservation planning device according to the present disclosure is the first structural example including: a conserved energy information storing portion that stores, for each customer, information regarding the amount of energy conserved in an electric power conservation period that has been performed, for customers who have executed electric power conservation measures in the past, wherein: the customer selecting portion selects candidate customers sequentially starting with the customers for which the environmental degradation levels calculated by the evaluating device are the smallest, calculate, from information stored in the conserved energy information storing portion, the total energy conservation amount for all of the selected candidate customers, and repeats selection of candidate customers until the total conserved energy amount is no less than a target energy conservation amount.

Moreover, the electric power conservation planning device according to the present disclosure is the first structural example further including: an electric power conservation requesting portion that requests, from the candidate customers selected by the customer selecting portion, electric conservation; and a request response controlling portion that cases the customer selecting portion to select an additional candidate customer when there is a candidate customer that refuses the request for energy conservation.

Moreover, an evaluating method, includes: an environment information obtaining step for obtaining, for each individual customer, environment information during an electric power conservation period for customers who have performed electric power conservation measures; an environment evaluating step for calculating, for each individual customer, an environmental degradation level indicating the level of degradation experienced by the customer during previous electric power conservation periods, based on environment information stored in the environment information obtaining step.

Given the present invention, for customers that have performed electric power conservation measures, environment information from during electric power conservation periods is obtained for each customer, and, based on that environment information, the environmental degradation is calculated for each customer, to enable an evaluation of the degree of degradation experienced by customers in electric power conservation periods in the past. Following this, if the result of this evaluation is reflected into electric power conservation plans, this can be expected to facilitate garnering of the cooperation of the customers.

Moreover, in the present disclosure, selecting candidate customers to be subject to electric power conservation sequentially beginning with the customers wherein the environmental degradation, calculated by the evaluating portion, is the least, makes it possible to make it unlikely for a customer that has experienced great environmental degradation to be selected to be subject to electric power conservation thereafter.

### BRIEF DESCRIPTIONS OF THE DRAWINGS

FIG. 1 is a block diagram illustrating the structure of an electric power conservation planning device according to an example according to the present disclosure.

FIG. 2 is a flowchart illustrating the operation of an electric power conservation planning device according to the example according to the present disclosure.

FIG. 3 is a flowchart illustrating the operation of a customer selecting portion according to the example according to the present disclosure.

FIG. 4 is a block diagram illustrating the structure of an environmental degradation evaluating device according to the example according to the present disclosure.

FIG. 5 is a block diagram illustrating the structure of an environment evaluating portion for an environmental degradation evaluating device according to the example according to the present disclosure.

FIG. 6 is a flowchart illustrating the operation of an environment evaluating portion of an environmental degradation level evaluating device according to the example according to the present disclosure.

FIG. 7 is a diagram for explaining a method for calculating the environmental degradation in the example according to the present disclosure.

FIG. 8 is a diagram for explaining a method for calculating the environmental degradation in another example according to the present disclosure.

### DETAILED DESCRIPTION

When reducing demand for electric power in order to balance supply and demand, there is a high probability of this leading to inconvenience or damage to the environment within buildings, such as an increase in the dissatisfaction of the customer or a reduction in productivity, through the deterioration of the occupied environment on the customer side (hereinafter termed “environmental degradation”). Given this, the present inventors focused on the fact that even in the case when energy conservation measures that, at first glance, appear to be fair, such as uniformly setting the temperature, when cooling, to 28° C. is applied, a situation is produced within actual buildings that cannot be considered fair due to the effects on comfort within the building (such as the comfort index, PMV, or the like) of conditions that each vary depending on, for example, the performance level of the building insulation, the area of openings, the orientation, internal heat producing factors (facilities and equipment, occupants), and the like. Moreover, the customers in office buildings that are occupied exclusively by employees of the company and customers such as with shops and stores and hotels, and the like, that seek to provide high-quality environments to their customers, will have different degrees in the effects of this on business.

That is, when energy reduction policies are put in place in a customer building, then the degree of degradation that can be allowed in the environment will differ greatly depending on the characteristics of the individual buildings, the surrounding environment, the nature of the business, and so forth. As a result, it will be difficult to obtain cooperation for energy reduction from customers wherein the environmental degradation tolerance level has been exceeded, and thus the inventors arrived to the idea that it is possible to improve cooperative sentiments if an evaluation result of the comfort of the customer environment, or the like, is used as an index for determining energy reduction measures in a manner that is more convincing for the customer.

Forms for carrying out the present disclosure will be explained below in reference to the figures. In the present example, the degree of environmental degradation experienced by the individual customer during an electric power conservation period (for example, during a demand response), which is a period wherein electric power conservation countermeasures are executed (where the degree of degradation is for example, the cumulative time over which discomfort has continued, or the degree of discomfort, a time ratio of discomfort, or the like) is evaluated, and the greater the environmental degradation, the less likely that customer is to be selected as subject to electric power conservation thereafter.

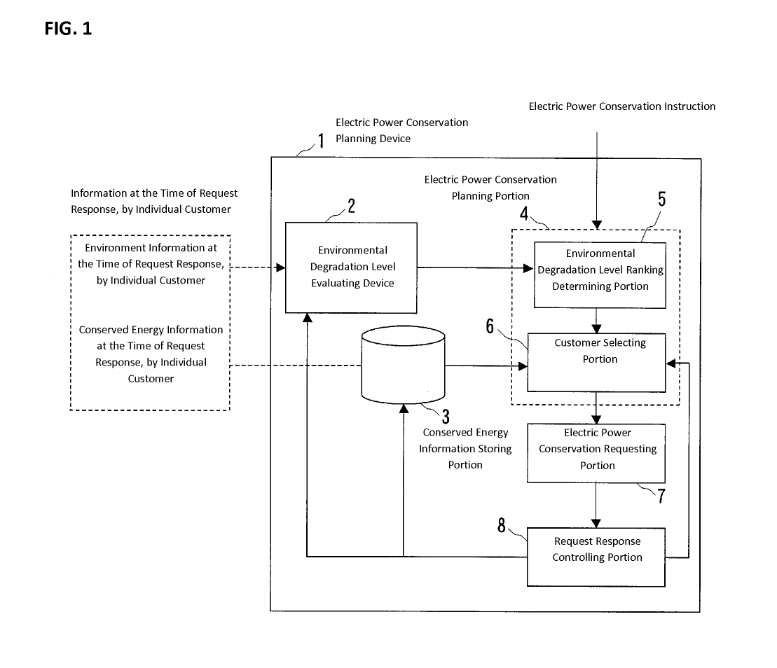

FIG. 1 is a block diagram illustrating a structure of an electric power conservation planning device according to the present example. The electric power conservation planning device 1 in the present example includes: an environmental degradation evaluating device 2, an energy conservation information storing portion 3, an electric power conservation planning portion 4, an electric power conservation requesting portion 7, and a request response controlling portion 8. The electric power conservation planning portion 4 is made from an environmental degradation ranking determining portion 5 and a customer selecting portion 6.

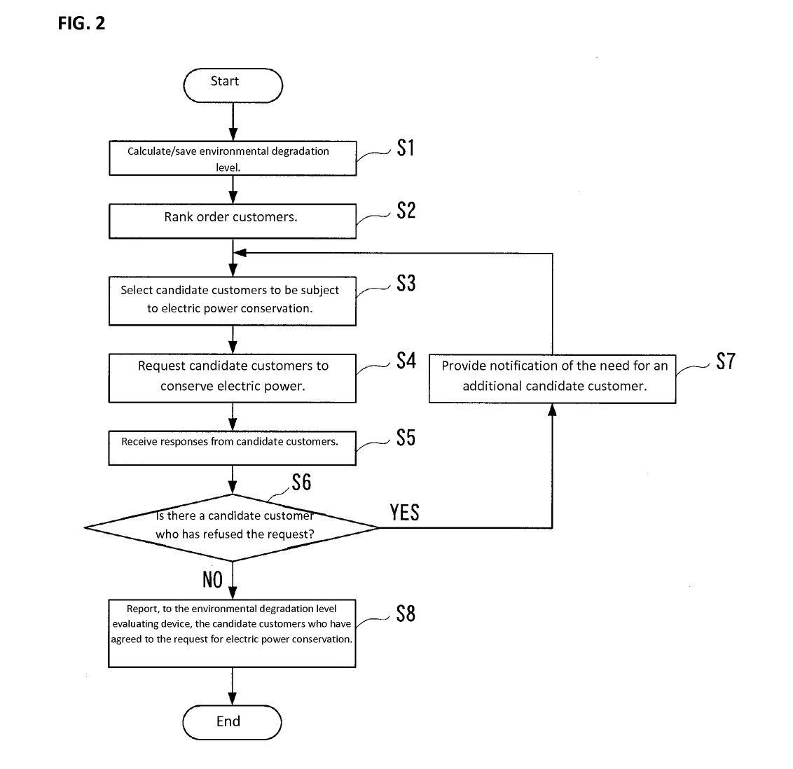

The operation of the electric power conservation planning device 1 according to the present example will be explained next using FIG. 2. The environmental degradation evaluating device 2 obtains, for each customer, environment information during an electric power conservation period for customers that have executed electric power conservation measures, and based on the environment information that is obtained, an environmental degradation level, which indicates the degree of degradation experienced by the customer during electric power conservation periods in the past is calculated and stored for each customer (Step S1 in FIG. 2). The details of the environmental degradation evaluating device 2 will be described in detail below.

The environmental degradation ranking determining portion 5 compares the degrees of environmental degradation calculated by the environmental degradation evaluating device 2, to rank order the customers (Step S2 in FIG. 2). The rank ordering of the customers may be from low to high or from high to low for the degree of environmental degradation. However, in the customer selecting portion 6, described below, candidate customers to be subject to electric power conservation are selected from the customers for which the degree of environmental degradation is low, and thus it is necessary for the relationship between the rank ordering of the customers and the priority order of the customer selection to be controlled by the environmental degradation level ranking determining portion 5 and the customer selecting portion 6. Normally, rank ordering is applied to the customers in the order from the least environmental degradation level, and typically that order is used as-is as the selection priority order.

Next, the conserved energy information storing portion 3, for the customers who have executed electric power conservation measures in the past, stores, for each individual customer, information on the amount of energy conservation (amount of energy conserved) that has been performed during the energy conservation periods.

The customer selecting portion 6 selects a candidate customer to be subjected to energy conservation, based on the conserved energy information stored in the conserved energy information storing portion 3 and the rankings for the individual customers, determined by the environmental degradation level ranking determining portion 5 (Step S3 in FIG. 2).

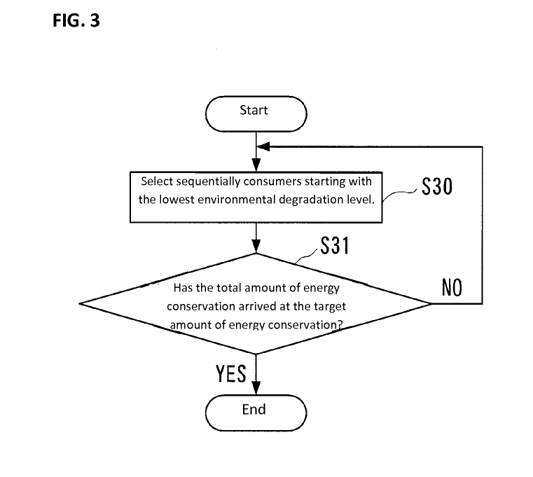

FIG. 3 is a flowchart illustrating the operation of the customer selecting portion 6. The target energy conservation amount is indicated through an electric power conservation instruction that is inputted from the outside to the customer selecting portion 6. The customer selecting portion 6 selects candidate customers to be subject to electric power conservation sequentially from the customers wherein the environmental degradation level is small (Step S30 in FIG. 3), and repeats the selections in Step S30 until the amount of conserved energy for the total of all of the selected candidate customers is equal to or greater than the target amount of conserved energy (YES in Step S31 in FIG. 3). All of the candidate customers to be subject to electric power conservation are selected in this way.

The electric power conservation requesting portion 7 requests electric power conservation for the candidate customers selected by the customer selecting portion 6 (Step S4 in FIG. 2). The requesting method may be, for example, requests through automated telephone calls to the candidate customers, requests through transmission of electronic mail, or the like.

Following this, the request response controlling portion 8 receives responses from the candidate customers who have been requested to conserve electric power, and stores information as to whether or not the candidate customers have consented to the requests (Step S5 in FIG. 2). For example, if the request for electric power conservation is made to a candidate customer through an automated telephone call, then the pressing of a specific first button (for example “1”) on the telephone by the candidate customer in response to the call may be considered to be consent to the request, where the pressing of a specific second button (for example, “9”) on the telephone by the candidate customer may be viewed as a refusal to the request. Moreover, if the candidate customer does not respond within a specific amount of time from the automated telephone call being placed, this may be interpreted as a refusal to the request. Moreover, when electric power conservation is requested from the candidate customer through transmission of an electronic e-mail, if a return mail is received within a specific time interval from the transmission of the mail, this may be interpreted as a consent to the response, but if no response mail is received within the specific period of time after transmission of the mail, then this may be viewed as a refusal to the request.

If there is a candidate customer who refuses the request for the electric power conservation (YES in Step S6 in FIG. 2), then the request response controlling portion 8 provides notification to the customer selecting portion 6 that it is necessary to select an additional candidate customer (Step S7 in FIG. 2).

The customer selecting portion 6, having received the notification from the request response controlling portion 8 returns to Step S3, to select an additional candidate customer. At this time, the customer selecting portion 6 selects an additional candidate customer from among all of the customers, excluding the candidate customers that have already been selected, in sequence beginning with the customers for which the environmental degradation level is small, based on the rank ordering of the individual customers, determined by the environmental degradation level ranking determining portion 5, and on the conserved energy information stored in the conserved energy information storing portion 3 (Step S30 in FIG. 3), and then repeats the selection of additional candidate customers until the total of the amount of energy conservation by those candidate customers that have already been selected who are candidate customers that have approved the request for electric power conservation and the amount of energy conservation of the candidate customer who is added equals or is greater than the target energy conservation (the YES in Step S31 in FIG. 3).

The electric power conservation requesting portion 7 requests electric power conservation for an additional candidate customers selected by the customer selecting portion 6 (Step S4 in FIG. 2).

Following this, the request response controlling portion 8 receives responses from the additional candidate customers who have been requested to conserve electric power, and stores information as to whether or not the additional candidate customers have consented to the requests (Step S5 in FIG. 2).

In this way, the processes of Step S3 through S7 are repeated until there is no candidate customer who has refused the request for energy conservation (NO in Step S6 of FIG. 2).

When approval of enough candidate customers to achieve the target energy conservation has been obtained, the request response controlling portion 8 reports ID information for specifying the candidate customers who have agreed to the requests to the environmental degradation level evaluating device 2 (Step S8 in FIG. 2).

Additionally, a demand controlling device, not shown, executes electric power conserving measures (stopping or changing the operations of facilities and equipment) in relation to the candidate customers who have agreed to the electric power conservation requests. Such demand control is disclosed in, for example, the JP '639.

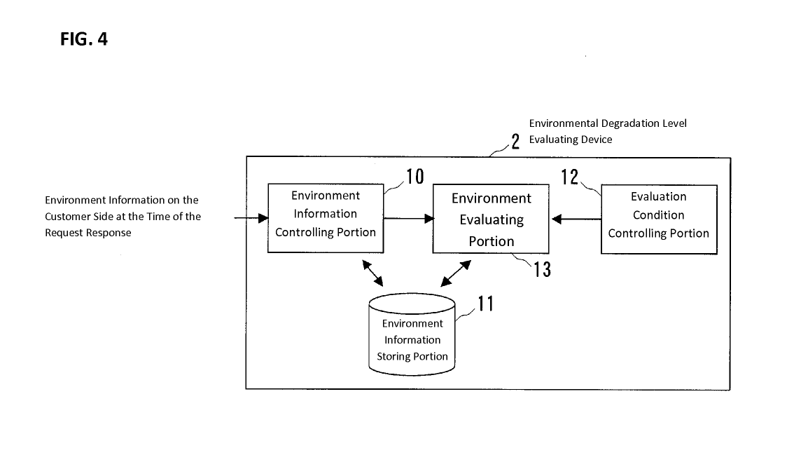

The environmental degradation level evaluating device 2 will be explained in detail next. FIG. 4 is a block diagram illustrating a structure for the environmental degradation level evaluating device 2. The environmental degradation level evaluating device 2 is provided with an environment information controlling portion 10, an environment information recording portion 11, an evaluation conditions controlling portion 12, and an environment evaluating portion 13.

The environment information controlling portion 10 obtains, for each customer, environment information from during the electric power conservation periods, and information for specifying the electric power conservation periods, for each of the customers that have implemented the electric power conservation measures. For the environment information, there is, for example, the indoor temperature, humidity, and the like. Sensors for measuring the environment information are disposed in the building on the customer side, to obtain environment information through an environment information collecting device (not shown) on the customer side. This environment information that has been obtained from the customer side is added to the ID information that specifies the customer. Note that in the present example, the environment information is time-series measurement values that are measured at uniform time intervals.

The environment information controlling portion 10 stores, in the environment information storing portion 11, the environment information that has been obtained, information specifying the electric power conservation periods, and ID information for specifying customers. Here the information for specifying the electric power conservation periods is obtained from the environment information collecting device on the customer side, but the system may instead be such that it is obtained from a demand controlling device for executing the electric power conservation measures.

Note that in order to calculate the degree of environmental degradation for the customer, if the environment information of the customer during electric power conservation periods in the past is to be obtained from the customer side, then it is necessary for the environment information collecting device on the customer side to store the environment information during the electric power conservation periods of the past. Given this, rather than obtaining the environment information when calculating the degree of environmental degradation of the customer, instead the environment information may be obtained from the environment information obtained device on the customer side while the electric power conservation measures are being executed, for the customers for whom the IDs have been reported by the request response controlling portion 8.

The evaluation conditions controlling portion 12 stores, in advance, information for specifying the method for evaluating the environmental degradation. This information is set by the provider or service company. As the information for setting the method for evaluating the degree of environmental degradation, there is, for example, information for specifying the method for calculating an environment evaluation index value for evaluating the environment of the customer, information for specifying the acceptable conditions for the environment evaluation index value, information for specifying the method for calculating the environment degradation value, and the like.

As the environment evaluation index value for evaluating the environment of the customer, the room temperature, discomfort index, PMV (Predicted Mean Vote) that indicates the level of comfort, or the like, may be used.

The discomfort index is calculated from environment information for the customer (the room temperature and humidity). When the discomfort index is used as the environment evaluation index value, the method for calculating the discomfort index is set up in the environment condition controlling portion 12.

Moreover, while the PMV may also be calculated from the environment information of the customer (the room temperature and humidity), along with room temperature and humidity, information such as, for example, the average radiation temperature, air speed, amount of clothing, metabolic rate, and the like, are required. Reference values are used for these unclear information. When the PMV is used for the environment evaluation index value, the method for calculating the PMV is set up in the evaluation condition controlling portion 12. Calculations for the discomfort index, PMV, and the like, such as listed above, are well known technologies, so detailed explanations thereof will be omitted.

Note that the environment information (room temperature and humidity) used in calculating the discomfort index or the PMV is determined in agreement with the customer. Moreover, the environment information may be through measurement values at representative points within the building, indicated by the customer, and may be average values or weighted-average values of measured values at a plurality of measurement points. The average values for the environment information at the plurality of measurement points may be calculated by the environment information collecting device on the customer side, or may be calculated by the environment evaluating portion 13. If the average values for the environment information are calculated by the environment evaluating portion 13, then information indicating the method for calculating the average values of the environment information is included in the information for specifying the method for calculating the environment evaluation index values.

Moreover, even when room temperature itself is used as the environment evaluation index value, the room temperature that is included in the environment information may be a measured value at a representative point in the building, specified by the customer, or may be an average value, or a weighted average value, of measurement values from a plurality of measurement points. If the average values for the room temperature are calculated by the environment evaluating portion 13, then information indicating the method for calculating the average values of the room temperature is included in the information for specifying the method for calculating the environment evaluation index values.

As values that are used as acceptable conditions for the environment evaluation index value, there are, for example, upper and lower limit values for the acceptable range for the environment evaluation index value. When the environment evaluation index value is outside of the acceptable range, specified by the upper and lower limit values, then it is determined that the customer is affected by the environmental degradation. Note that the acceptable conditions for the environmental evaluation index value may be determined for each individual customer, or may be conditions that are common to all of the customers.

When the environment evaluation index value acceptable range is specified by upper and lower limit values, then the time over which the environment evaluation index value is outside of the acceptable range during an electric power conservation period may be calculated as the degree of environmental degradation. Conversely, the integral value for the environment evaluation index values that have gone outside of the acceptable range during the electric power conservation periods may be used as the degree of environmental degradation.

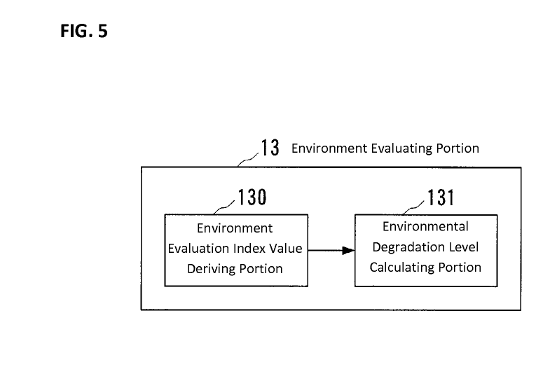

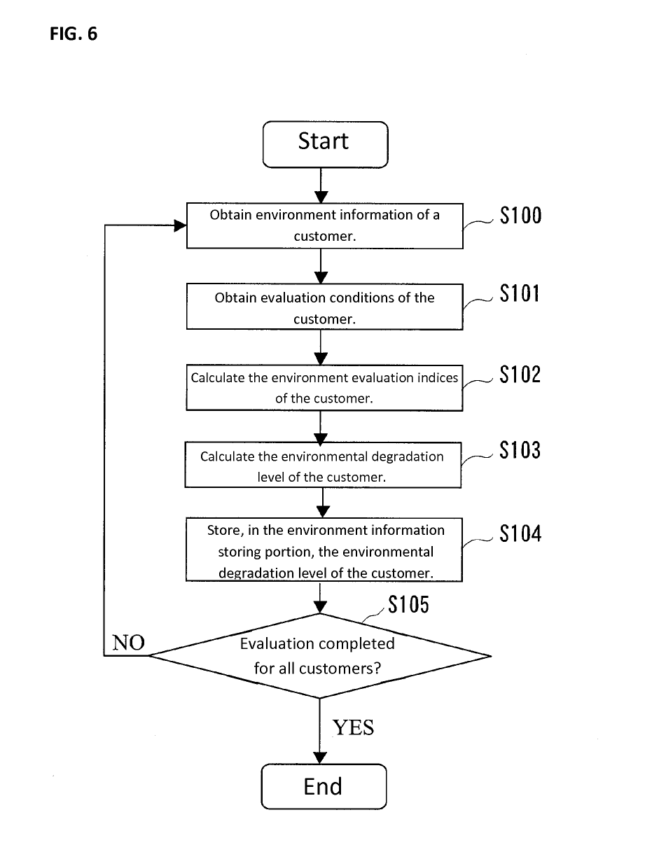

FIG. 5 is a block diagram illustrating a structure of an environment evaluating portion 13, and FIG. 6 is a flowchart illustrating the operation of the environment evaluating portion 13. The environment evaluating portion 13 is provided with an environment evaluation index value deriving portion 130 and an environmental degradation calculating portion 131.

The environment evaluation index value deriving portion 130 of the environment evaluating portion 13, when attempting to calculate the degree of environmental degradation for the customer, obtains the customer environment information, the information that specifies the electric power conservation periods, and the ID information that specifies the customer, from the environment information storing portion 11 (Step S100 in FIG. 6), obtains, from the evaluation condition controlling portion 12, information that specifies the method for calculating the environment evaluation index value, information that specifies the acceptable conditions for the environment evaluation index value, and information specifying the method for calculating the degree of environmental degradation (Step S101 in FIG. 6), and calculates the environment evaluation index value for the customer from the environment information that has been obtained (Step S102 in FIG. 6). As described above, the environment evaluation index value may be the room temperature, a discomfort index, the PMV, or the like.

Additionally, the environmental degradation calculating portion 131 of the environment evaluating portion 13 evaluates whether or not the customer environment evaluation index value is outside of the acceptable range, calculates the degree of environmental degradation for the customer based on this evaluation result (Step S103 in FIG. 6), and stores, in the environment information storing portion 11, the calculated degree of environmental degradation and information for specifying the electric power conservation periods, linked to the information that specifies the customer (the ID) (Step S104 in FIG. 6). The processes even Step S100 through S104 as set forth above are performed repetitively until the environmental degradation has been calculated for all of the applicable customers (YES in Step S105 of FIG. 6).

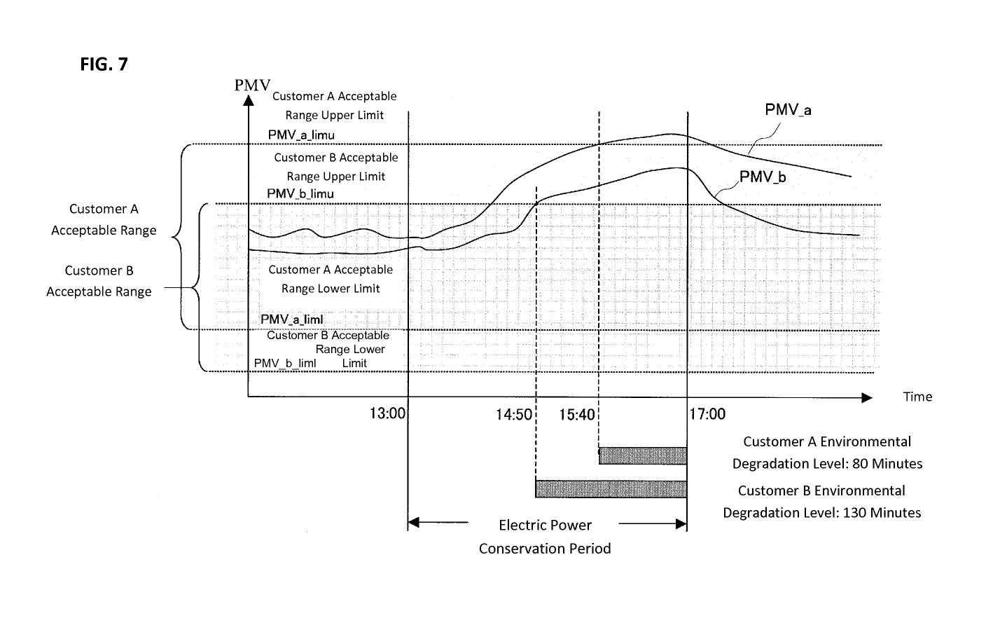

For example, a case wherein the PMV is used as the environment evaluation index value to specify upper and lower limit values for the acceptable range for the environment evaluation index value, and the amount of time, within the electric power conservation period, that the environment evaluation index value is outside of the acceptable range, is used as the environmental degradation level is illustrated in FIG. 7. In FIG. 7, the PMV for a customer A defined as PMV_a, and the PMV for a customer B is defined as PMV_b. The upper limit value for the acceptable range for customer A is PMV_a_limu, and the lower limit value for the acceptable range is PMV_a_liml. The upper limit value for the acceptable range for customer B is PMV_b_limu, and the lower limit value for the acceptable range is PMV_b_liml. The electric power conservation period was from 1:00 p.m. to 5:00 p.m. For customer A, the time over which the PMV_a was outside of the acceptable range was from 1:40 p.m. until 5:00 p.m. Consequently, the degree of environmental degradation for customer A was 80 min. For customer B, the time over which the PMV _b was outside of the acceptable range was from 2:50 p.m. until 5:00 p.m. Consequently, the degree of environmental degradation for customer B was 130 min.

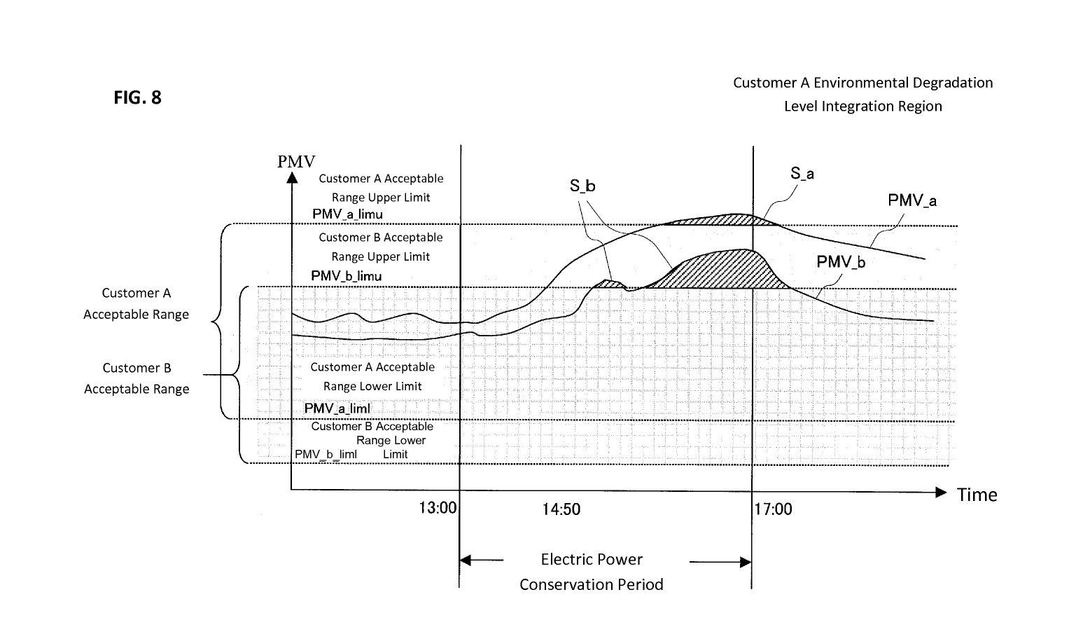

A case wherein the PMV is used as the environment evaluation index value to specify upper and lower limit values for the acceptable range for the environment evaluation index value, and the integral value, within the electric power conservation period, of the environment evaluation index value that is outside of the acceptable range, is used as the environmental degradation level is illustrated in FIG. 8. As with the example in FIG. 7, the electric power conservation time was from what 1:00 p.m. until 5:00 p.m. When the integral value when the environment evaluation index is outside of the acceptable range is used as the environmental degradation level, the environmental degradation level for customer A is the area of the shaded portion S_a of FIG. 8, and the environmental degradation level for customer B is the area of the shaded portion S_b of FIG. 8.

At this time, the environmental degradation level D for customer A can be calculated as the value that is the integral value of the absolute value |PMV_a−PMV_a_limu| of the difference between the environment evaluation index PMV_a and the upper limit value PMV_a_limu or the integral value of the absolute value |PMV_a−PMV_a_liml| of the difference between the environment evaluation index PMV_a and PMV_a_liml, for each time the environment evaluation index value PMV_a goes outside of the acceptable range during the electric power conservation period.

$$\begin{matrix}Expression 1 & \\ D = {\sum }_{nu = 1}^{P} \{ \int \vert PMV\_a - PMV\_a \_limu \vert d t \} + {\sum }_{n 1 = 1}^{Q} \{ \int \vert PMV\_a - PMV\_a \_lim \vert d t \} & ( 1 )\end{matrix}$$

In Expression (1), nu =P is the number of times that the environment evaluation index value PMV_a for the customer A exceeded the upper limit value PMV_a_limu of the acceptable range during the electric power conservation period, and nl=Q is the number of times that the environment evaluation index value PMV_a for the customer A was outside of the lower limit value PMV_a_liml of the acceptable range during the electric power conservation period. Note that the time interval from the environment evaluation index value PMV_a rising above the upper limit value PMV_a_limu until returning to the upper limit value PMV_a_limu is counted as once, and the time interval from the environment evaluation index value PMV_a falling below the lower limit value PMV_a_liml until returning to the lower limit value PMV_a_liml is counted as once. Consequently, in Expression (1) the ∫|PMV_a−PMV_a_limu|dt is the value for the integral from when the environment evaluation index value PMV_a rose above the upper limit value PMV_a_limu until it returned to the upper limit value PMV_{—} a_limu, and the ∫|PMV_a−PMV_a_liml|dt is the value for the integral from when the environment evaluation index value PMV_a fell below the lower limit value PMV_a_liml until it returned to the lower limit value PMV_a_liml. The environmental degradation level evaluating device 2 is able to calculate the environmental degradation level for the customer as described above.

The electric power conservation planning device 1 explained in the present example may be embodied through a computer that is equipped with a CPU, a storage device, and an interface, combined with a program for controlling these hardware resources. The CPU executes the processes described in the present example in accordance with a program that is stored in the storage device. In the example in FIG. 1, the environmental degradation level evaluating device 2 is provided within the electric power conservation planning device 1, but, conversely, may be provided outside of the electric power conservation planning device 1 instead. When the environmental degradation level evaluating device 2 and the electric power conservation planning device 1 are each separate devices, the CPUs of the respective devices perform the processes described in the present example in accordance with programs that are stored in storage devices of the respective devices.

The present invention can be applied to technologies for controlling electric power demand of customers.

Obviously, numerous modifications and variations of the present invention are possible in light of the above teachings. It is therefore to be understood that within the scope of the appended claims, the invention may be practiced otherwise than as specifically described herein.

1. An evaluating device comprising:
an environment information controlling portion that obtains, for each individual customer, environment information during an electric power conservation period for customers who have performed electric power conservation measures;
an environment information storing portion that stores environment information obtained from the environment information controlling portion; and
an environment evaluating portion that calculates, for each individual customer, an environmental degradation level indicating the level of degradation experienced by the customer during previous electric power conservation periods, based on environment information stored in the environment information storing portion.

2. The evaluating device as set forth in claim 1, wherein:
the environment evaluating portion comprise:
an environment evaluation index value deriving portion that calculates an environment evaluation index value for evaluating the environment of the customer from the environment information; and
an environmental degradation level calculating portion that evaluates whether or not the environment evaluation index value is outside of an acceptable range, and that calculates an environmental degradation level based on the evaluation result.

3. The evaluating device as set forth in claim 2, wherein:
the environmental degradation level calculating portion calculates, as the environmental degradation level, the time over which the environment evaluation index value is outside of the acceptable range extends, within the electric power conservation period, or calculate, as the environmental degradation level, an integral value of the environment evaluation index value that is outside of the acceptable range during the electric power conservation period.

4. The electric power conservation planning device comprising:
an evaluating device as set forth in claim 1; and
a customer selecting portion that selects candidate customers, to be subject to electric power conservation, in ascending order starting with the customer for which the environmental degradation level calculated by the evaluating device is smallest.

5. The electric power conservation planning device as set forth in claim 4, further comprising:
a conserved energy information storing portion that stores, for each customer, information regarding the amount of energy conserved in an electric power conservation period that has been performed, for customers who have executed electric power conservation measures in the past, wherein:
the customer selecting portion selects candidate customers sequentially starting with the customers for which the environmental degradation levels calculated by the evaluating device are the smallest, calculates, from information stored in the conserved energy information storing portion, the total energy conservation amount for all of the selected candidate customers, and repeats selection of candidate customers until the total conserved energy amount is no less than a target energy conservation amount.

6. The electric power conservation planning device as set forth in claim 4, further comprising:
an electric power conservation requesting portion that requests, from the candidate customers selected by the customer selecting portion, electric conservation; and
a request response controlling portion that cases the customer selecting portion to select an additional candidate customer when there is a candidate customer that refuses the request for energy conservation.

7. An evaluating method, comprising:
an environment information obtaining step for obtaining, for each individual customer, environment information during an electric power conservation period for customers who have performed electric power conservation measures;
an environment evaluating step for calculating, for each individual customer, an environmental degradation level indicating the level of degradation experienced by the customer during previous electric power conservation periods, based on environment information stored in the environment information obtaining step.

8. The evaluating method as set forth in claim 7, wherein:
the environment evaluating step includes:
an environment evaluation index value deriving step for calculating an environment evaluation index vain and lue for evaluating the environment of the customer from the environment information; and
an environmental degradation level calculating step for evaluating whether or not the environment evaluation index value is outside of an acceptable range, and for calculating an environmental degradation level based on the evaluation result.

9. The evaluating method as set forth in claim 8, wherein:
the environmental degradation level calculating step calculates, as the environmental degradation level, the time over which the environment evaluation index value is outside of the acceptable range extends, within the electric power conservation period, or calculates, as the environmental degradation level, an integral value of the environment evaluation index value that is outside of the acceptable range during the electric power conservation period.

10. The electric power conservation planning method, comprising:
each of the steps set forth in claim 7; and
a candidate consumer selecting step for selecting, candidate consumers to be subject to electric power conservation, sequentially from the consumers wherein the environmental degradation level is the smallest.

11. The electric power conservation planning method as set forth in claim 10, wherein:
the candidate customer selecting step includes a step for referencing a conserved energy information storing portion for storing, for each customer, information for the amounts of conserved energy within the electric power conserving periods that have been performed in the past, to calculate, from the information that is stored in the conserved energy information storing portion, the total amount of energy conserved by all of the selected candidate customers, to repeatedly select candidate customers until the total amount of energy conserved is at least target amount of served energy.

12. The electric power conservation planning method as set forth in claim 10, further comprising:
an electric power conservation requesting for requesting, from the candidate customers selected by the customer selecting step, electric conservation; and
an additional candidate customer selecting step for selecting an additional candidate customer by executing again the candidate customer selecting step if there is a candidate customer who has refused the electric power conservation request.
